(19) United States
(12) Patent Application Publication
(10) Pub. No.: US 2025/0048651 A1
(43) Pub. Date: Feb. 6, 2025

(54) MANUFACTURING METHOD OF SEMICONDUCTOR DEVICE

(71) Applicant: SK hynix Inc., Icheon-si (KR)

(72) Inventors: Yoon Mo KOO, Icheon-si (KR); Hyung Dong LEE, Icheon-si (KR)

(21) Appl. No.: 18/428,376

(22) Filed: Jan. 31, 2024

(30) Foreign Application Priority Data
Aug. 3, 2023 (KR) 10-2023-0101627

(51) Int. Cl. H10B 63/00; H10B 63/10

(52) U.S. Cl. CPC H10B 63/84; H10B 63/10; H10B 63/24

(57) ABSTRACT

A manufacturing method may include: forming first memory stack lines extending in a first direction; forming first access lines on the first memory stack lines to extend in a second direction intersecting the first direction, each first access line being electrically conductive to provide an electrical connection; forming a second memory stack on the first access lines; and forming first trenches extending between the first access lines to separate the second memory stack into second memory stack lines extending in the second direction, and to separate the first memory stack lines into first memory cells.

### CROSS-REFERENCE TO RELATED APPLICATION

This patent document claims, under 35 U.S.C. § 119, the priority to and benefits of the Korean Patent Application No. 10-2023-0101627 filed on Aug. 3, 2023, which is incorporated herein by reference in its entirety.

### TECHNICAL FIELD

Embodiments of the present disclosure relate to structures and configurations of memory devices for storing data, and manufacturing of a semiconductor device with the memory devices.

### BACKGROUND

Recently, in accordance with the miniaturization, low power consumption, performance improvement, diversification, and the like, of electronic devices, semiconductor devices capable of storing information in various electronic devices such as computers and portable communication devices have been demanded. Accordingly, research into a semiconductor device capable of storing data using characteristics of switching between different resistance states depending on an applied voltage or current has been conducted. Examples of such a semiconductor device include a resistive random access memory (RRAM), a phase-change random access memory (PRAM), a ferroelectric random access memory (FRAM), a magnetic random access memory (MRAM), an E-fuse, etc.

In order to decrease a size of the semiconductor device and increase data storage capacity of the semiconductor device, the semiconductor device has been developed so that many memory cells may be integrated in the same area by reducing a metal line width on a two-dimensional plane.

However, as the metal line width is reduced on the two-dimensional plane, there is a problem that manufacturing equipment, investment cost, and development period increase exponentially. Accordingly, a method of manufacturing a semiconductor device in a three-dimensional structure has been researched and developed.

### SUMMARY

In an embodiment, a manufacturing method of a semiconductor device may include: forming first memory stack lines extending in a first direction; forming first access lines on the first memory stack lines to extend in a second direction intersecting the first direction, each first access line being electrically conductive to provide an electrical connection; forming a second memory stack on the first access lines; and forming first trenches extending between the first access lines to separate the second memory stack into second memory stack lines extending in the second direction, and to separate the first memory stack lines into first memory cells.

In an embodiment, a manufacturing method of a semiconductor device may include: forming first memory stack lines extending in a first direction; forming first access lines on the first memory stack lines, the first access lines extending in a second direction intersecting the first direction; forming sacrificial layers between the first access lines; forming a second memory stack on the first access lines and the sacrificial layers; forming a first mask pattern on the second memory stack, the mask pattern covering the first access lines and exposing the sacrificial layers; and forming second memory stack lines and first memory cells by etching the second memory stack, the sacrificial layers, and the first memory stack lines using the first mask pattern as an etching barrier, the second memory stack lines extending in the second direction.

### BRIEF DESCRIPTION OF THE DRAWINGS

FIG. 1 is an example of a perspective view illustrating a structure of a semiconductor device in accordance with an embodiment of the disclosed technology.

FIG. 2 is an example of a perspective view illustrating a structure of a semiconductor device in accordance with another embodiment.

FIGS. 3A, 4A, 5A, 6A, 7A, 8A, 9A, 10A, and 11A are examples of cross-sectional views that illustrate a manufacturing method in accordance with an embodiment of the disclosed technology.

FIGS. 3B, 4B, 5B, 6B, 7B, 8B, 9B, 10B, and 11B are examples of cross-sectional views that illustrate a manufacturing method in accordance with an embodiment of the disclosed technology.

FIGS. 3C, 4C, 5C, 6C, 7C, 8C, 9C, 10C, and 11C are examples of plan views that illustrate a manufacturing method in accordance with an embodiment of the disclosed technology.

### DETAILED DESCRIPTION

Various embodiments are directed to a manufacturing method of a semiconductor device including a plurality of memory decks that are stacked one another.

With the trend toward miniaturization, the metal line width in a semiconductor device is reduced on the two-dimensional plane, which causes to require a new advanced manufacturing equipment and increase the cost investment and the development period. Various implementations of the disclosed technology may be used to provide a method of manufacturing a semiconductor device in a three-dimensional structure instead of a two-dimensional structure. Specifically, the disclosed technology may be implemented to design and manufacture a three-dimensional cross point memory structure for use in memory devices.

For example, various implementations of the disclosed technology provide a manufacturing method of a semiconductor device including a first memory deck and a second memory deck that share an access line to access the first and second memory decks. Such implementations for sharing an access line for different memory decks may be advantageously used to improve an alignment issue of the access lines of the first memory deck and the second memory deck. In some implementations, by forming access lines to be shared by the first and second memory decks that are tacked to each other and then forming a trench penetrating through first and second memory stacks between the access lines, it is possible to decrease damage to memory cells formed on the access lines during an etching process for forming the trench.

Hereafter, various embodiments of the disclosed technology will be described with reference to the accompanying drawings.

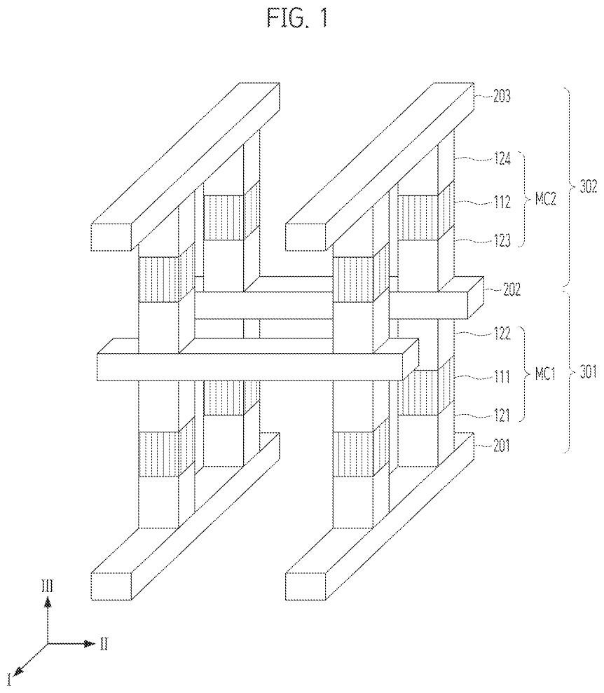

FIG. 1 is a perspective view for describing the structure of a semiconductor device in accordance with an embodiment of the disclosed technology where columns of stacked memory cells (e.g., MC1, 301 and MC2, 302 in each of 4 illustrated columns) are connected via access lines 201, 202 and 203 to form a 3-dimensional array of memory cells.

The semiconductor device in accordance with an embodiment may be a memory device having a three-dimensional cross point array structure. The semiconductor device may include access lines located on different layers, and may include memory cells located in a region where the access lines extending in different directions intersect each other. In addition, the semiconductor device may include a structure in which a plurality of memory decks, e.g., memory deck 301 and memory deck 302 as shown, are stacked over one another along a vertical direction that is substantially perpendicular to a substrate on which the memory cells are supported and/or formed.

Referring to the specific example in FIG. 1, the semiconductor device may include a first memory deck 301 and a second memory deck 302. The second memory deck 302 may be stacked on the first memory deck 301 such that the second memory deck 302 is disposed or stacked over the first memory deck 301 along a vertical direction II as shown in FIG. 1. Referring to the Cartesian coordinate shown in FIG. 1, a first direction I and a second direction II may be directions intersecting each other in a plane parallel to a substrate that supports the memory decks a third direction III may be a direction perpendicular to the plane defined by the first direction I and the second direction II.

The first memory deck 301 may include at least one first access line 201, at least one first memory cell MC1 for data storage, and at least one second access line 202, or combinations thereof.

In the specific example in FIG. 1, the first access line 201 may extend in the first direction I. The second access line 202 may extend in in the second direction II perpendicular to the first direction I. The first access line 201 and the second access line 202 may be at different elevations or positions in the third direction II so that are the first and second access lines 201 and 202 are coupled to the two opposite sides of the first memory cell MC1 as shown. The first access line 201 and the second access line 202 may be a word line or a bit line in implementations. In an example, the first access line 201 may be a word line, and the second access line 202 may be a bit line. In another example, the first access line 201 may be a bit line, and the second access line 202 may be a word line. The first access line 201 and the second access line 202 may include a conductive material such as a polysilicon or metal. For example, the first and second access lines 201 and 202 may include a polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), molybdenum (Mo), ruthenium (Ru), or others, or combinations thereof. In an example, each of the first and second access lines 201 and 202 may include a metal such as tungsten (W).

The first memory cell MC1 may be located in a region where the first access line 201 and the second access line 202 intersect each other to form a 2-dimensional array of first memory cells MCs where first memory cells MC1 may be arranged in the first direction I and the second direction II. The first memory cell MC1 may be connected between the first access line 201 and the second access line 202.

The first memory cell MC1 may include a first lower electrode 121, a first variable resistance layer 111 for storing data based on a particular resistance state out of different resistance states, and a first upper electrode 122. While the example in FIG. 1 illustrates that the first memory cell MC1 includes the first variable resistance layer 111, the first memory cell MC1 may, in other implementations, further include a switching layer in addition to the first variable resistance layer 111 so that the switching layer is used to control the access to the first variable resistance layer 111. Yet, in some other implementations, a single layer may be implemented in the first memory cell MC1 to provide both the data storage function and the switching function. The first variable resistance layer 111 and/or the switching layer may be located between the first lower electrode 121 and the first upper electrode 122. In an example, the first lower electrode 121, the first variable resistance layer 111, and the first upper electrode 122 may be stacked in the third direction Ill. The first lower electrode 121 may be electrically connected to the first access line 201. The first variable resistance layer 111 may operate to store data in the first memory cell MC1. The first variable resistance layer 111 may have a variable resistance characteristic that switches between different resistance states according to an applied voltage/current so that the different resistance states can be used to represent different stored data. In an example, the first variable resistance layer 111 may include a variable resistance material whose resistance changes without phase change or include a chalcogenide-based material. The switching layer may have a threshold switching characteristic, for example, a characteristic for blocking or substantially limiting current when a magnitude of an applied voltage is less than a predetermined threshold value and for allowing current to abruptly increase above the threshold value. The threshold value may be referred to as a threshold voltage, and the switching layer may be implemented in a turned-on state or a turned-off state based on the threshold voltage. For example, the switching layer may be turned on to be electrically conductive to allow the current to follow through when the magnitude of the applied voltage is greater than the threshold value and may be turned off to block or substantially limit current when the magnitude of the applied voltage is less than the threshold value. The description on the first variable resistance layer 111 and the switching layer, which are included in the first memory cell MC1, may be applied to the second variable resistance layer and the switching layer that are included in the second memory cell MC2. In addition, such description can be applied to variable resistance layers and switching layers of the semiconductor device base on other embodiments. The first lower electrode 121 and the first upper electrode 122 may include a conductive material such as carbon or metal nitride. For example, the first lower electrode 121 and the first upper electrode 122 may include tungsten (W), tungsten nitride (WNₓ), tungsten silicide (WSiₓ), titanium (Ti), titanium nitride (TiNx), titanium silicon nitride (TiSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), or others, or combinations thereof. In an example, each of the first lower electrode 121 and the first upper electrode 122 may include carbon (C).

The second memory deck 302, stacked over the first memory deck 301, may include at least one second access line 202, at least one second memory cell MC2 for data storage, and at least one third access line 203.

The second access line 202 may extend in the second direction II, as described above, and the third access line 203 may extend in the first direction I. The third access line 203 may be stacked on the second access line 202 in the third direction III so that the access lines 202 and 203 are at different elevations or positions in the third direction III to be electrically coupled to opposite sides of the memory deck 302. The third access line 203 may be a word line or a bit line. In an example, the second access line 202 may be a word line, and the third access line 203 may be a bit line. In another example, the second access line 202 may be a bit line, and the third access line 203 may be a word line. For example, the third access line 203 may include a polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), molybdenum (Mo), ruthenium (Ru), or others, or combinations thereof. In an example, the third access line 203 may include a metal such as tungsten (W).

The second memory cell MC2 may be located in a region where the second access line 202 and the third access line 203 intersect each other. The second memory cells MC2 may be arranged in the first direction I and the second direction II to form a 2-dimensional array of second memory cells MCs where the second memory cell MC2 may be connected between the second access line 202 and the third access line 203.

Referring to FIG. 1, the above two or more 2-dimensional arrays of memory cells MCs, e.g., the first 2-demensional array of memory cells MC1s and the second 2-demensional array of memory cells MC2s are stacked over, and spatially aligned with respect to, one another along the third direction III (the illustrated vertical direction in FIG. 1) to form a 3-dimensional array of memory cells that are coupled to the crossed and vertically stacked access lines 201, 202 and 203, etc.

The second memory cell MC2 may include a second lower electrode 123, a second variable resistance layer 112, and a second upper electrode 124, or combinations thereof. While the example in FIG. 1 illustrates that the second memory cell MC2 includes the second variable resistance layer 112, the second memory cell MC2 may, in other implementations, further include a switching layer in addition to the second variable resistance layer 112 so that the switching layer is used to control the access to the second variable resistance layer 112. Yet, in some other implementations, a single layer may be implemented in the second memory cell MC2 to provide both the data storage function and the switching function. The second variable resistance layer 112 or the switching layer may be located between the second lower electrode 123 and the second upper electrode 124. In an example, the second lower electrode 123, the second variable resistance layer 112, and the second upper electrode 124 may be stacked in the third direction III. The second lower electrode 123 may be electrically connected to the second access line 202. The second upper electrode 124 may be electrically connected to the third access line 203. At least one of the second lower electrode 123 and the second upper electrode 124 may include an insulating barrier therein. In an example, the second variable resistance layer 112 may be a memory layer of a memory element and a switching layer of a selection element. Thus, the second variable resistance layer 112 may function as the memory element and the selection element at the same time. The second variable resistance layer 112 may include a chalcogenide alloy. The second lower electrode 123 and the second upper electrode 124 may include a conductive material such as carbon or metal nitride. For example, the second lower electrode 123 and the second upper electrode 124 may include tungsten (W), tungsten nitride (WNₓ), tungsten silicide (WSiₓ), titanium (Ti), titanium nitride (TiNₓ), titanium silicon nitride (TiSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), or others, or combinations thereof. In an example, the second lower electrode 123 and the second upper electrode 124 may include carbon (C).

According to the structure described above, the first memory deck 301 and the second memory deck 302 may be stacked in the third direction III, and the first memory deck 301 and the second memory deck 302 may share the second access line 202 with each other. When the first and third access lines 201 and 203 are word lines, the second access line 202 may be a bit line. When the first and third access lines 201 and 203 are bit lines, the second access line 202 may be a word line.

When the first memory deck 301 and the second memory deck 302 do not share the second access lines and include their own second access lines, the second access line 202 of the first memory deck 301 and the second access line 202 of the second memory deck 302 are formed by separate processes. In such a case, the second access lines 202 may be misaligned with each other in a manufacturing process. Accordingly, by manufacturing the first memory deck 301 and the second memory deck 302 so as to share the second access line 202 with each other, it is possible to avoid or address an alignment issue that occurred when the first memory deck 301 and the second memory deck 302 of the second access lines 202.

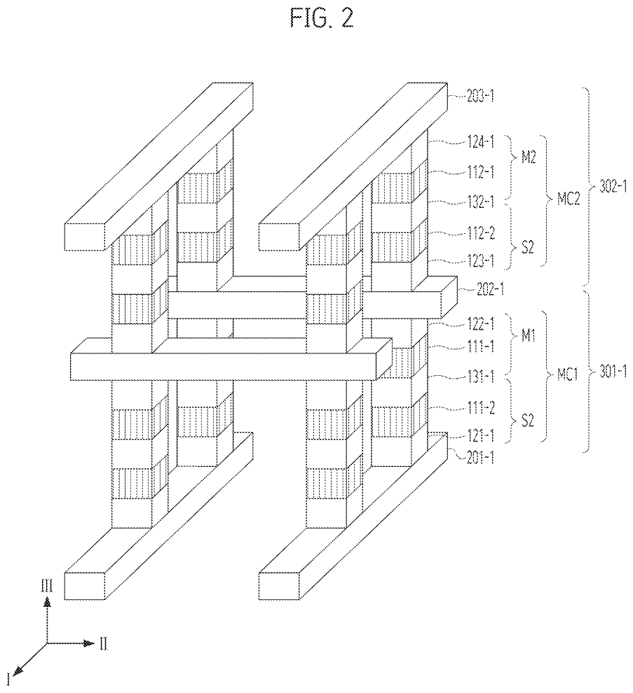

FIG. 2 is a perspective view illustrating an example of the structure of a semiconductor device in accordance with another embodiment of the disclosed technology. Similar to the example in FIG. 1, columns of stacked memory cells (e.g., MC1, 301 and MC2, 302 in each of 4 illustrated columns) are connected via access lines 201-1, 202-1 and 203-1 to form a 3-dimensional array of memory cells.

In various implementations, the semiconductor device illustrated in FIG. 2 may be different from the semiconductor device illustrated in FIG. 1 in configurations of memory cells, and may be similar to or the same as the semiconductor device illustrated in FIG. 1 in other configurations.

Referring to FIG. 2, the semiconductor device may include a first memory deck 301-1 and a second memory deck 302-1. The second memory deck 302-1 may be stacked on the first memory deck 301-1. Here, the first direction I and the second direction II may be directions intersecting each other. The third direction III may be a direction perpendicular to a plane defined by the first direction I and the second direction II.

The first memory deck 301-1 may include at least one first access line 201-1, at least one first memory cell MC1, and at least one second access line 202-1.

The first access line 201-1 may extend in the first direction I. The second access line 202-1 may extend in the second direction II. The first access line 201-1 and the second access line 202-1 may be stacked in the third direction III. The first access line 201-1 and the second access line 202-1 may be a word line or a bit line. In an example, the first access line 201-1 may be a word line, and the second access line 202-1 may be a bit line. In another example, the first access line 201-1 may be a bit line, and the second access line 202-1 may be a word line. The first and second access lines 201-1 and 202-1 may include a conductive material such as a polysilicon or metal. For example, the first and second access lines 201-1 and 202-1 may include a polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), molybdenum (Mo), ruthenium (Ru), or others, or combinations thereof. In an example, the first and second access lines 201-1 and 202-1 may include a metal such as tungsten (W).

The first memory cell MC1 may be located in a region where the first access line 201-1 and the second access line 202-1 intersect each other. The first memory cells MC1 may be arranged in the first direction I and the second direction II. The first memory cell MC1 may be connected between the first access line 201-1 and the second access line 202-1.

The first memory cell MC1 may include a first selection element S1 and a first memory element M1 connected in series and stacked over each other. The first selection element S1 may adjust a flow of a current through the cell MC1 according to a magnitude of an applied voltage or current. The first memory cell MC1 may be selected according to turn-on or turn-off of the first selection element S1 for accessing the first memory element M1 through this control of the first selection element S1. The first selection element S1 may include a first lower electrode 121-1, a first switching layer 111-2, and a first intermediate electrode 131-1. The first switching layer 111-2 may be located between the first lower electrode 121-1 and the first intermediate electrode 131-1. The first switching layer 111-2 may maintain a specific phase such as an amorphous phase during an operation of the first memory cell MC1. In an example, the first switching layer 111-2 may include a chalcogenide material. The first lower electrode 121-1 may be located between the first switching layer 111-2 and the first access line 201-1, and may be electrically connected to the first access line 201-1. The first lower electrode 121-1 and the first intermediate electrode 131-1 may include tungsten (W), tungsten nitride (WNₓ), tungsten silicide (WSiₓ), titanium (Ti), titanium nitride (TiNₓ), titanium silicon nitride (TiSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), or others, or combinations thereof. In an example, the first lower electrode 121-1 and the first intermediate electrode 131-1 may include carbon (C).

The first memory element M1 may include a first intermediate electrode 131-1, a first variable resistance layer 111-1 for storing data based on its different resistance states, and a first upper electrode 122-1. The first variable resistance layer 111-1 may be located between the first intermediate electrode 131-1 and the first upper electrode 122-1. The first selection element S1 and the first memory element M1 may share the first intermediate electrode 131-1 with each other. The first upper electrode 122-1 of the first memory element M1 may be electrically connected to the second access line 202-1. The first upper electrode 122-1 may include tungsten (W), tungsten nitride (WNₓ), tungsten silicide (WSiₓ), titanium (Ti), titanium nitride (TiNₓ), titanium silicon nitride (TiSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), or others, or combinations thereof. In an example, the first upper electrode 122-1 may include carbon (C).

The first variable resistance layer 111-1 may have characteristics of transitioning between different resistance states depending on a voltage or a current applied to the first memory element M1. In an example, when the first variable resistance layer 111-1 has a low resistance state, data ‘1’ may be stored, and when the first variable resistance layer 111-1 has a high resistance state, data ‘0’ may be stored.

In an example, the first variable resistance layer 111-1 may include a resistive material. An electrical path is generated or disappears in the first variable resistance layer 111-1, such that data may be stored. In an example, the first variable resistance layer 111-1 may include transition metal oxide or include a metal oxide such as a perovskite-based material.

In an example, the first variable resistance layer 111-1 may have a magnetic tunnel junction (MTJ) structure including a magnetization pinned layer, a tunnel barrier layer, and a magnetization free layer. The data may be stored according to a change in a magnetization direction of the magnetization free layer with respect to a magnetization direction of the magnetization pinned layer. In an example, the magnetization pinned layer and the magnetization free layer may include a magnetic material, and the tunnel barrier layer may include a metal oxide.

In an example, the first variable resistance layer 111-1 may include a phase change material or include a chalcogenide-based material. The first variable resistance layer 111-1 may change a phase according to a program operation. In an example, the first variable resistance layer 111-1 may have a low-resistance crystalline state through a set operation. In an example, the first variable resistance layer 111-1 may be have a high-resistance amorphous state through a reset operation. Accordingly, the data may be stored in the memory cell using a resistance difference according to a phase of the first variable resistance layer 111-1.

In an example, the first variable resistance layer 111-1 may include a variable resistance material whose resistance changes without phase change or include a chalcogenide-based material. The first variable resistance layer 111-1 may maintain its phase after the program operation. In an example, the first variable resistance layer 111-1 may have an amorphous state, and may maintain the amorphous state without changing to a crystalline state after the program operation. A threshold voltage of the memory cell may be changed depending on a program voltage applied to the memory cell, and the memory cell may be programmed to at least two states. In an example, memory cells may be programmed to a set state or reset state using program voltages having different polarities. Accordingly, the data may be stored in the memory cell using a difference in the threshold voltage of the memory cell.

The second memory deck 302-1 may include at least one second access line 202-1, at least one second memory cell MC2, and at least one third access line 203-1, or combinations thereof.

The second access line 202-1 may extend in the second direction II, as described above. The third access line 203-1 may extend in the first direction I. The second access line 202-1 and the third access line 203-1 may be stacked in the third direction Ill. The second access line 202-1 and the third access line 203-1 may be a word line or a bit line. In an example, the second access line 202-1 may be a word line, and the third access line 203-1 may be a bit line. Alternatively, the second access line 202-1 may be a bit line, and the third access line 203-1 may be a word line. The third access line 203-1 may include a conductive material such as a polysilicon or metal, like the first and second access lines 201-1 and 202-1. For example, the third access line 203-1 may include a polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), molybdenum (Mo), ruthenium (Ru), or others, or combinations thereof. In an example, the third access line 203-1 may include a metal such as tungsten (W).

The second memory cell MC2 may be located in a region where the second access line 202-1 and the third access line 203-1 intersect each other. The second memory cells MC2 may be arranged in the first direction I and the second direction II. The second memory cell MC2 may be connected between the second access line 202-1 and the third access line 203-1.

The second memory cell MC2 may include a second selection element S2 and a second memory element M2. The second selection element S2 may adjust a flow of a current according to a magnitude of an applied voltage or current. The second memory cell MC2 may be selected according to turn-on or turn-off of the second selection element S2 for accessing the second memory element M2 through this control of the second selection element S2. The second selection element S2 may include a second lower electrode 123-1, a second switching layer 112-2, and a second intermediate electrode 132-1. The second switching layer 112-2 may be located between the second lower electrode 123-1 and the second intermediate electrode 132-1. The second switching layer 112-2 may maintain a specific phase such as an amorphous phase during an operation of the second memory cell MC2. In an example, the second switching layer 112-2 may include a chalcogenide material. The second lower electrode 123-1 may be located between the second switching layer 112-2 and the second access line 202-1, and may be electrically connected to the second access line 202-1. The second lower electrode 123-1 and the second intermediate electrode 132-1 may include tungsten (W), tungsten nitride (WNₓ), tungsten silicide (WSiₓ), titanium (Ti), titanium nitride (TiNₓ), titanium silicon nitride (TiSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), or others, or combinations thereof. In an example, the second lower electrode 123-1 and the second intermediate electrode 132-1 may include carbon (C).

The second memory element M2 may include a second intermediate electrode 132-1, a second variable resistance layer 112-1, and a second upper electrode 124-1. The second variable resistance layer 112-1 may be located between the second intermediate electrode 132-1 and the second upper electrode 124-1. The second selection element S2 and the second memory element M2 may share the second intermediate electrode 132-1 with each other. The second upper electrode 124-1 of the second memory element M2 may be electrically connected to the third access line 203-1. The second upper electrode 124-1 may include tungsten (W), tungsten nitride (WNₓ), tungsten silicide (WSiₓ), titanium (Ti), titanium nitride (TiNx), titanium silicon nitride (TiSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), or others, or combinations thereof. In an example, the second intermediate electrode 131-1 and the second upper electrode 124-1 may include carbon (C).

The second variable resistance layer 112-1 may have characteristics of reversibly transitioning between different resistance states depending on a voltage or a current applied to the second memory element M2. In an example, when the second variable resistance layer 112-1 has a low resistance state, data ‘1’ may be stored, and when the second variable resistance layer 112-1 has a high resistance state, data ‘0’ may be stored. In an example, the second variable resistance layer 112-1 may include a resistive material, a phase change material, or a chalcogenide-based material, like the first variable resistance layer 111-1. Alternatively, the second variable resistance layer 112-1 may have an MTJ structure including a magnetization pinned layer, a tunnel barrier layer, and a magnetization free layer.

Like the semiconductor device in accordance with an embodiment illustrated in FIG. 1, in the semiconductor device in accordance with the present disclosure illustrated in FIG. 2, the first memory deck 301-1 and the second memory deck 302-1 may be stacked in the third direction Ill, and the first memory deck 301-1 and the second memory deck 302-1 may share the second access line 202-1 with each other. When the first and third access lines 201 and 203 are word lines, the second access line 202 may be a bit line. When the first and third access lines 201 and 203 are bit lines, the second access line 202 may be a word line.

When the first memory deck 301-1 and the second memory deck 302-1 do not share the second access lines and include their own second access lines, the second access line 202-1 of the first memory deck 301-1 and the second access line 202-1 of the second memory deck 302-1 are formed by separate processes. In such a case, the second access lines 202-1 may be misaligned with each other in a manufacturing process. Accordingly, by manufacturing the first memory deck 301-1 and the second memory deck 302-1 so as to share the second access line 202-1 with each other, it is possible to avoid or address an alignment issue that occurred when the first memory deck 301-1 and the second memory deck 302-1 of the second access lines 202-1.

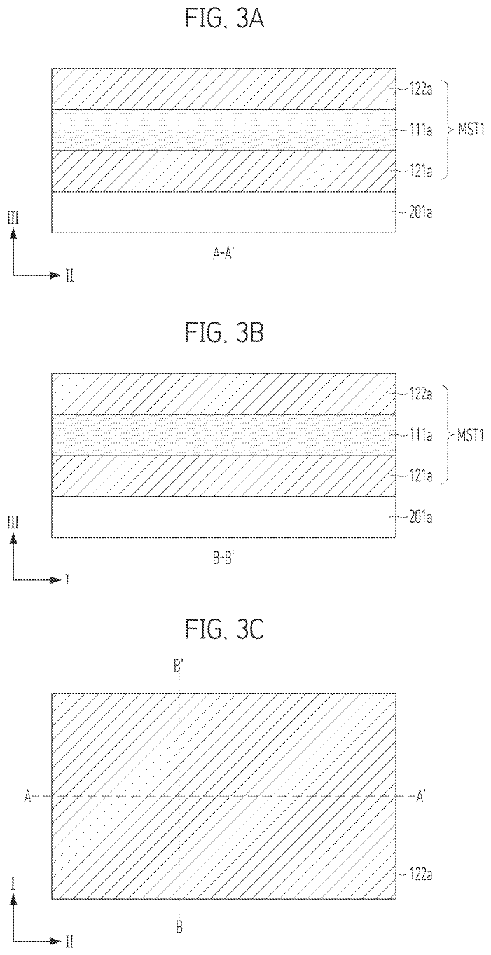

FIGS. 3A to 11C are diagrams for describing a manufacturing method of a semiconductor device in accordance with an embodiment. FIGS. 3C, 4C, 5C, 6C, 7C, 8C, 9C, 10C, and 11C may be plan views, FIGS. 3A, 4A, 5A, 6A, 7A, 8A, 9A, 10A, and 11A may be cross-sectional views taken along lines A-A′ of FIGS. 3C, 4C, 5C, 6C, 7C, 8C, 9C, 10C, and 11C, respectively, and FIGS. 3B, 4B, 5B, 6B, 7B, 8B, 9B, 10B, and 11B may be cross-sectional views taken along lines B-B′ of FIGS. 3C, 4C, 5C, 6C, 7C, 8C, 9C, 10C, and 11C, respectively.

Referring to FIGS. 3A, 3B, and 3C, a first conductive layer 201a and a first memory stack MST1 may be formed. The first conductive layer 201a can be made of or can include a conductive material such as a metal, and may include a polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), molybdenum (Mo), ruthenium (Ru), or others, or combinations thereof. In an example, the first conductive layer 201a may include a metal such as tungsten (W).

The first memory stack MST1 may be formed on the first conductive layer 201 a. In an example, the first memory stack MST1 may include a first lower electrode layer 121a, a first variable resistance layer 111a for storing data, and a first upper electrode layer 122a. In an example, the first lower electrode layer 121a may be formed on the first conductive layer 201a. The first variable resistance layer 111a may be formed on the first lower electrode layer 121a. The first upper electrode layer 122a may be formed on the first variable resistance layer 111a. For example, the first lower electrode layer 121a and the first upper electrode layer 122a may include tungsten (W), tungsten nitride (WNₓ), tungsten silicide (WSiₓ), titanium (Ti), titanium nitride (TiNₓ), titanium silicon nitride (TiSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), or others, or combinations thereof. In an example, the first lower electrode layer 121a and the first upper electrode layer 122a may include carbon (C). The first variable resistance layer 111a may include a resistive material, a phase change material, or a variable resistance material whose resistance changes without phase change. The first variable resistance layer 111a may include a chalcogenide-based material. Alternatively, the first variable resistance layer 111a may have an MTJ structure including a magnetization pinned layer, a tunnel barrier layer, and a magnetization free layer.

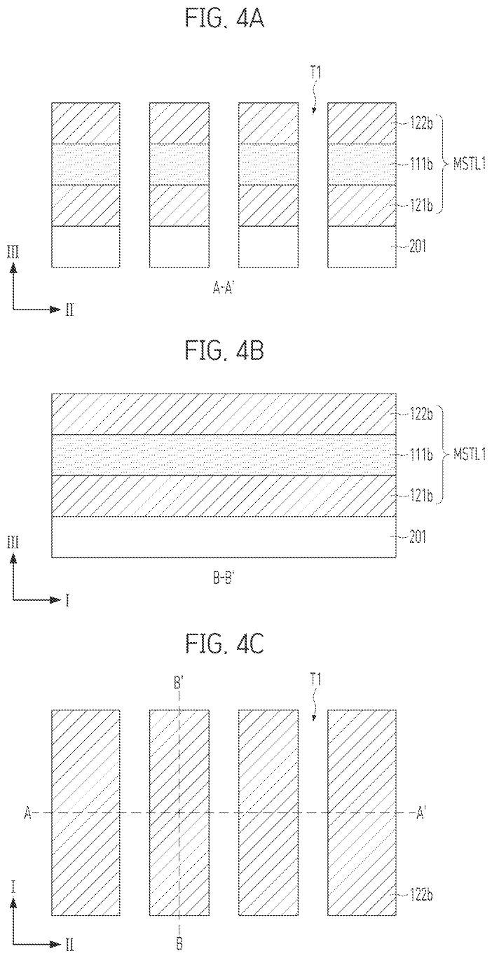

Referring to FIGS. 4A, 4B, and 4C, first memory stack lines MSTL1 and first access lines 201 may be formed. First trenches T1 penetrating through the first memory stack MST1 and the first conductive layer 201 a and extending in the first direction I may be formed. The first trenches T1 may be formed by forming a mask pattern extending in the first direction I on the first memory stack MST1 and etching the first memory stack MST1 and the first conductive layer 201a using the mask pattern as an etching barrier. Accordingly, the first trenches T1 may be formed to extend in the first direction I in a plan view and extend in the third direction III in a cross-sectional view.

The first trenches T1 may penetrate the first memory stack MST1 and separate the first memory stack MST1 into the first memory stack lines MSTL1. The first memory stack lines MSTL1 may include first upper electrode lines 122b, first variable resistance lines 111b, first lower electrode lines 121b that are formed from the first upper electrode layer 122a, the first variable resistance layer 111a, and the first lower electrode layer 121a, respectively. In addition, the first trenches T1 may penetrate the first conductive layer 201 a and separate the first conductive layer 201 a into the first access lines 201 extending in the first direction I.

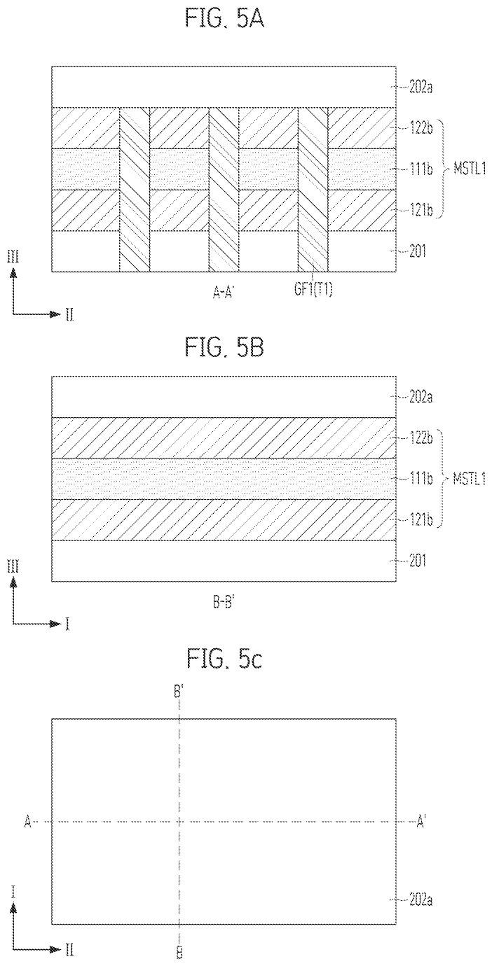

Referring to FIGS. 5A, 5B, and 5C, insulating layers, e.g., first gap-fill insulating layers GF1, and a second conductive layer 202a may be formed. The insulating layers may be disposed between two adjacent first memory stack lines. In some implementations, the insulating layers may be disposed to fill the gap between the first memory stack lines and thus referred to as the gap-fill insulating layers GF1. The first gap-fill insulating layers GF1 may be formed in the first trenches T1. Subsequently, the second conductive layer 202a extending in the first direction I and the second direction II may be formed on the first upper electrode lines 122b and the first gap-fill insulating layers GF1. In some implementations, the first gap-fill insulating layer GF1 may include an insulating material such as oxide, nitride, air gap, or void. The second conductive layer 202a may include a metal such as tungsten (W).

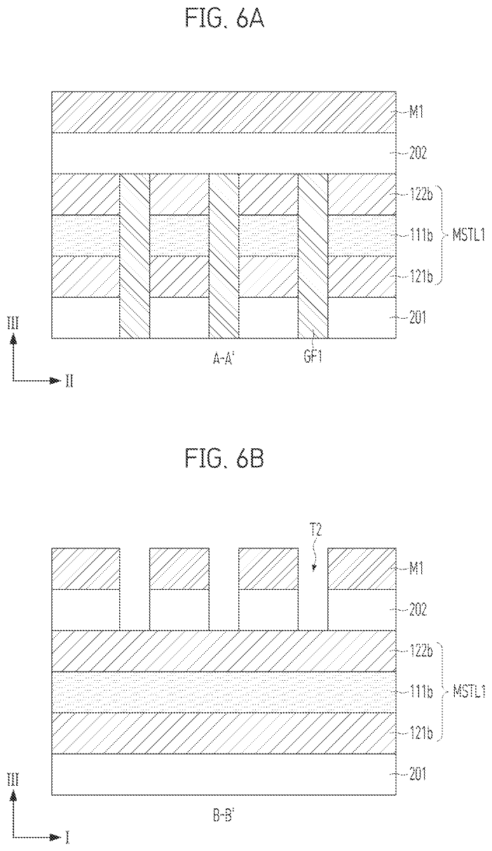

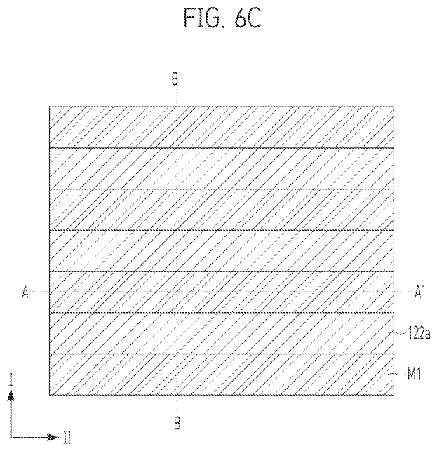

Referring to FIGS. 6A, 6B, and 6C, second access lines 202 may be formed. First, a first mask pattern M1 extending in the second direction II may be formed on the second conductive layer 202a. Subsequently, the second conductive layer 202a may be etched using the first mask pattern M1 as an etching barrier until the first upper electrode lines 122b are exposed. Consequently, second trenches T2 extending in the second direction II may be formed. The second trenches T2 may separate the second conductive layer 202a into the second access lines 202. The second trenches T2 may be located between the second access lines 202.

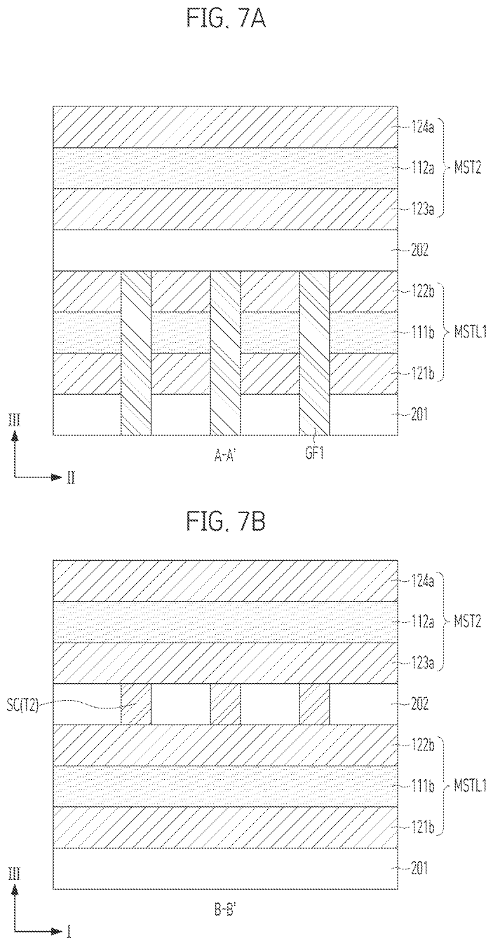

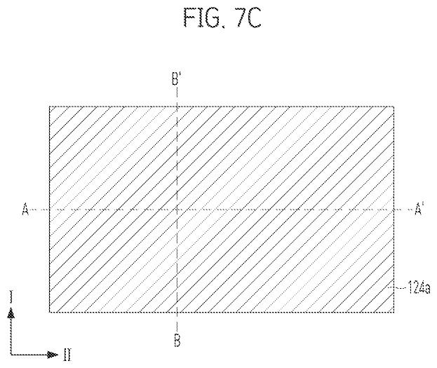

Referring to FIGS. 7A, 7B, and 7C, a second memory stack MST2 may be formed. First, sacrificial layers SC may be formed in the second trenches T2, and the first mask pattern M1 may be removed. The second memory stack MST2 may be formed on the second access lines 202 and the sacrificial layers SC. In some implementations, the second memory stack MST2 may include a second lower electrode layer 123a, a second variable resistance layer 112a, and a second upper electrode layer 124a. In an example, the second lower electrode layer 123a may be formed on the second access lines 202 and the sacrificial layers SC. The second variable resistance layer 112a may be formed on the second lower electrode layer 123a. The second upper electrode layer 124a may be formed on the second variable resistance layer 112a. The second lower electrode layer 123a and the second upper electrode layer 124a may include tungsten (W), tungsten nitride (WNx), tungsten silicide (WSix), titanium (Ti), titanium nitride (TiNx), titanium silicon nitride (TiSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), or others, or combinations thereof. In an example, the second lower electrode layer 123a and the second upper electrode layer 124a may include carbon (C). The second variable resistance layer 112a may include a resistive material, a phase change material, or a variable resistance material whose resistance changes without phase change. The second variable resistance layer 112a may include a chalcogenide-based material. Alternatively, the second variable resistance layer 112a may have an MTJ structure including a magnetization pinned layer, a tunnel barrier layer, and a magnetization free layer.

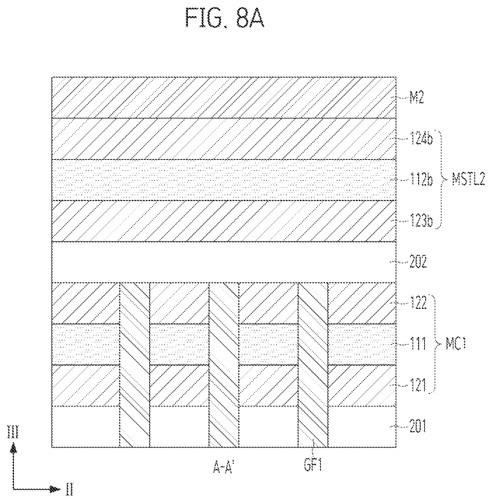

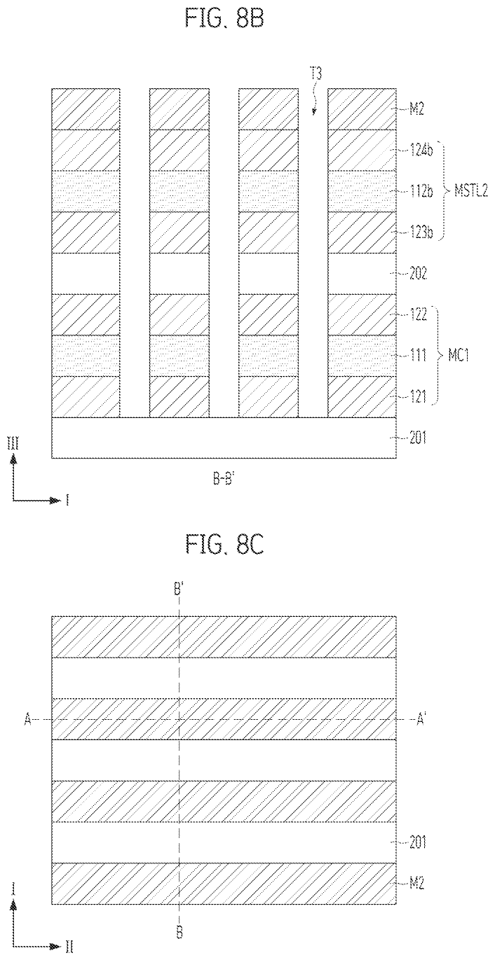

Referring to FIGS. 8A, 8B, and 8C, second memory stack lines MSTL2 and first memory cells MC1 may be formed. First, a second mask pattern M2 extending in the second direction II may be formed on the second memory stack MST2. In some implementations, the second mask pattern M2 may have a shape in which it covers the second access lines 202 and exposes the sacrificial layers SC. The second mask pattern M2 may have the same shape as the first mask pattern M1. Subsequently, the second memory stack MST2, the sacrificial layers SC, and the first memory stack lines MSTL1 may be etched using the second mask pattern M2 as an etching barrier. The sacrificial layers SC may be removed in an etching process using the second mask pattern M2 as the etching barrier. Consequently, third trenches T3 extending in the second direction II in a plan view and extending in the third direction III in a cross-sectional view may be formed. The third trenches T3 may be formed to have a depth enough to expose the first access lines 201.

The third trenches T3 may separate the second memory stack MST2 into the second memory stack lines MSTL2. The third trenches T3 may be located between the second access lines 202. The third trenches T3 may separate the first memory stack lines MSTL1 into the first memory cells MC1. In some implementations, the second memory stack lines MSTL2 may include second lower electrode lines 123b, second variable resistance lines 112b, and second upper electrode lines 124b that extend in the second direction II. Each of the first memory cells MC1 may include a first lower electrode 121 separated from the first lower electrode lines 121b, a first variable resistance layer 111 separated from the first variable resistance lines 111b, and a first upper electrode 122 separated from the first upper electrode lines 122b.

When the second conductive layer 202a is etched while forming the third trenches T3, the second conductive layer 202a may be etched in a state in which the second memory stack lines MSTL2, particularly the second variable resistance lines 112b, are exposed. Thus, in a process of etching the second conductive layer 202a, the second memory stack lines MSTL2, particularly the second variable resistance lines 112b, may be damaged.

According to an embodiment of the present disclosure, the second access lines 202 are formed by etching the second conductive layer 202a in advance, e.g., before forming the third trenches T3. Thus, it is possible to reduce damage to the second memory stack lines MSTL2 in a process of forming the third trenches T3.

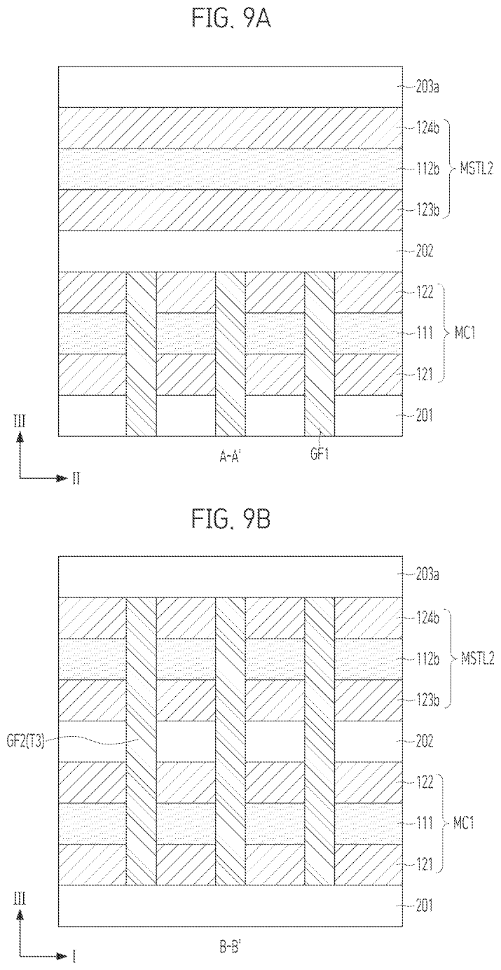

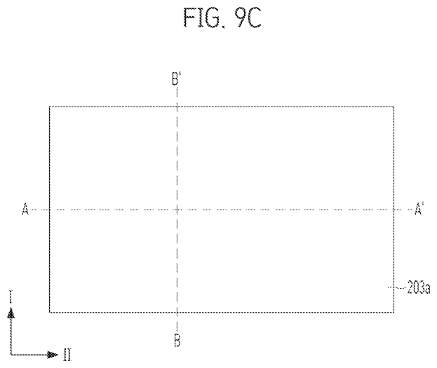

Referring to FIGS. 9A, 9B, and 9C, a third conductive layer 203a may be formed. First, second gap-fill insulating layers GF2 may be formed in the third trenches T3, and the second mask pattern M2 may be removed. Subsequently, the third conductive layer 203a may be formed on the second upper electrode lines 124b and the second gap-fill insulating layers GF2. In some implementations, the second gap-fill insulating layer GF2 may include an insulating material such as oxide, nitride, air gap, or void. The third conductive layer 203a may include a metal such as tungsten (W).

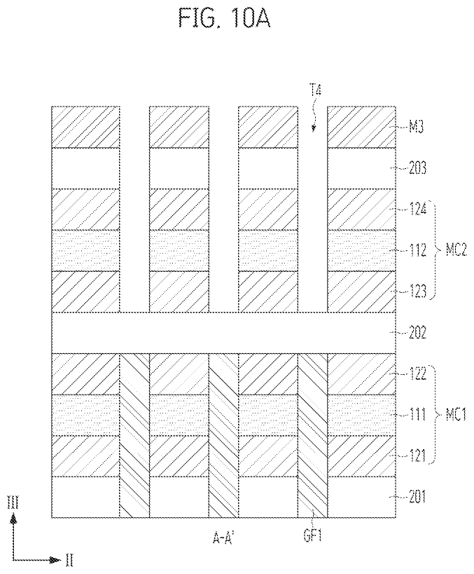

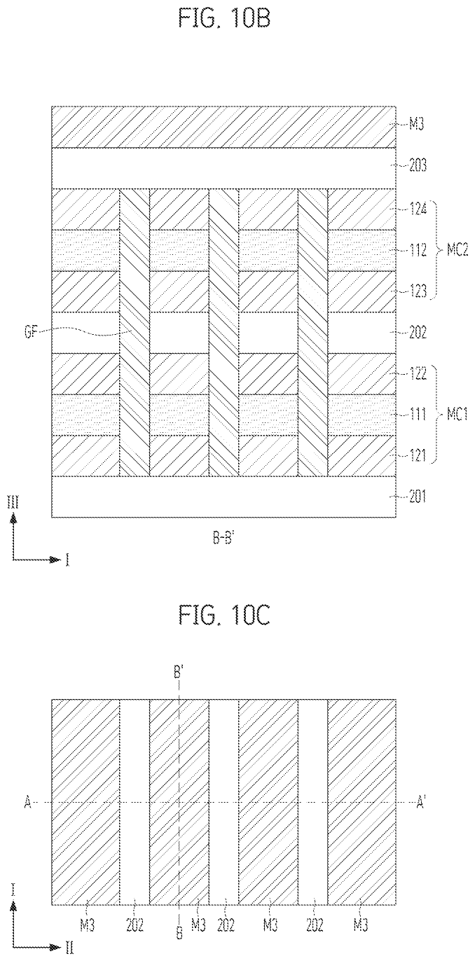

Referring to FIGS. 10A, 10B, and 10C, the third access line 203 and second memory cells MC2 may be formed. First, a third mask pattern M3 extending in the first direction I may be formed on the third conductive layer 203a. The third conductive layer 203a and the second memory stack lines MSTL2 may be etched using the third mask pattern M3 as an etching barrier. Consequently, fourth trenches T4 may be formed. The fourth trenches T4 may be formed to have a depth enough to expose the second access lines 202. The fourth trenches T4 may separate the third conductive layer 203a into the third access lines 203. The fourth trenches T4 may separate the second memory stack lines MSTL2 into the second memory cells MC2. Each of the second memory cells MC2 may include a second lower electrode 123 separated from the second lower electrode lines 123b, a second variable resistance layer 112 separated from the second variable electrode lines 112b, and a second upper electrode 124 separated from the second upper electrode lines 124b.

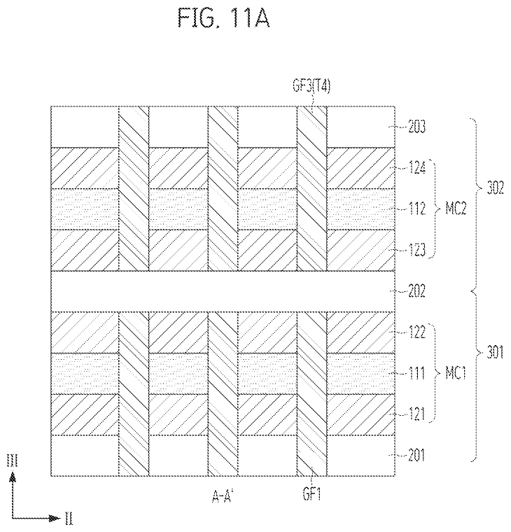

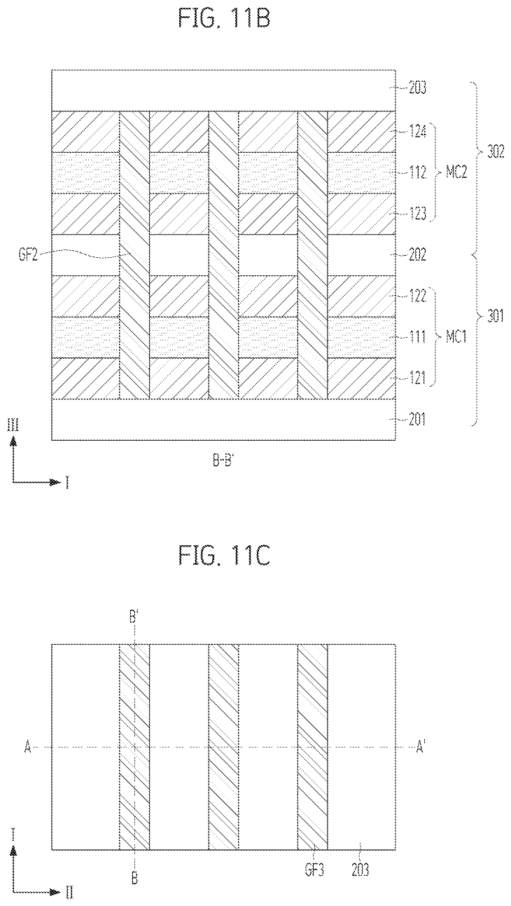

Referring to FIGS. 11A, 11B, and 11C, third gap-fill insulating layers GF3 may be formed in the fourth trenches T4, and the third mask pattern M3 may be removed.

In the manufacturing method of a semiconductor device in accordance with an embodiment, the first access lines 201 extending in the first direction I may be formed, the second access lines 202 extending in the second direction II may be formed on the first access lines 201, and the third access lines 203 extending in the first direction I may be formed on the second access lines 202. In addition, in the manufacturing method of a semiconductor device in accordance with an embodiment, the first memory cells MC1 may be formed between the first access lines 201 and the second access lines 202, and the second memory cells MC2 may be formed between the second access lines 202 and the third access lines 202. Accordingly, in the manufacturing method of a semiconductor device in accordance with an embodiment, a first memory deck 301 including the first access lines 201, the first memory cells MC1, and the second access lines 202 may be formed. In addition, a second memory deck 301 sharing the second access lines 202 with the first memory deck 310 and including the second access line 202, the second memory cells MC2, and the third access lines 203 may be stacked and formed on the first memory deck 301.

In the manufacturing method in accordance with an embodiment, in a manufacturing process of forming the first memory deck 301 and the second memory deck 302 stacked to share the second access line 202 with each other, the third trenches T3 are formed after the second access lines 202 are formed, and it is thus possible to reduce damage to the second memory stack lines MSTL2. In some implementations, the third trenches T3 may be trenches separating the second memory stack MST2 into the second memory stack lines MSTL2 while separating the first memory stack lines MSTL1 into the first memory cells MC1.

Although the present disclosure has been described above with reference to some specific examples of certain implementations of the disclosed embodiments and the accompanying drawings, the scope of the present disclosure is not limited to the above examples of implementations of the disclosed embodiments. Various types of substitutions, modifications, changes, and/or improvements for the disclosed embodiments and other embodiments may be made based on what is disclosed and/or illustrated in this patent document.

What is claimed is:

1. A manufacturing method for manufacturing a semiconductor device, comprising:
forming first memory stack lines extending in a first direction;
forming first access lines on the first memory stack lines to extend in a second direction intersecting the first direction, each first access line being electrically conductive to provide an electrical connection;
forming a second memory stack on the first access lines; and
forming first trenches extending between the first access lines to separate the second memory stack into second memory stack lines extending in the second direction, and to separate the first memory stack lines into first memory cells.

2. The manufacturing method of claim 1, wherein the forming of the first memory stack lines comprises:
forming a lower electrode layer;
forming a variable resistance layer on the lower electrode layer;
forming an upper electrode layer on the variable resistance layer; and
forming second trenches by etching the upper electrode layer, the variable resistance layer, and the lower electrode layer.

3. The manufacturing method of claim 2, wherein the variable resistance layer includes a phase change material.

4. The manufacturing method of claim 2, wherein the variable resistance layer includes a chalcogenide material maintaining its phase after a program operation.

5. The manufacturing method of claim 2, further comprising forming first insulating layers to fill in the second trenches.

6. The manufacturing method of claim 1, wherein the forming of the first access lines comprises:
forming a first conductive layer on the first memory stack lines;
forming third trenches extending in the second direction by etching the first conductive layer; and
forming sacrificial layers in the third trenches.

7. The manufacturing method of claim 6, wherein the forming of the first trenches comprises etching the sacrificial layers such that the first trenches extend to locations between the first access lines.

8. The manufacturing method of claim 7, further comprising forming second insulating layers to fill in the first trenches.

9. The manufacturing method of claim 1, further comprising:
forming a second conductive layer on the second memory stack lines; and
forming fourth trenches separating the second conductive layer into second access lines extending in the first direction and separating the second memory stack lines into second memory cells.

10. The manufacturing method of claim 9, further comprising forming third insulating layers to fill in the fourth trenches.

11. A manufacturing method of a semiconductor device, the manufacturing method comprising:
forming first memory stack lines extending in a first direction;
forming first access lines on the first memory stack lines, the first access lines extending in a second direction intersecting the first direction;
forming sacrificial layers between the first access lines;
forming a second memory stack on the first access lines and the sacrificial layers;
forming a first mask pattern on the second memory stack, the mask pattern covering the first access lines and exposing the sacrificial layers; and
forming second memory stack lines and first memory cells by etching the second memory stack, the sacrificial layers, and the first memory stack lines using the first mask pattern as an etching barrier, the second memory stack lines extending in the second direction.

12. The manufacturing method of claim 11, further comprising:
forming a first conductive layer on the second memory stack lines; and
forming second access lines and second memory cells by etching the first conductive layer and the second memory stack lines, the second access lines extending in the first direction.

13. The manufacturing method of claim 11, wherein the forming of the first memory stack lines comprises:
forming a lower electrode layer;
forming a variable resistance layer on the lower electrode layer;
forming an upper electrode layer on the variable resistance layer; and
etching the upper electrode layer, the variable resistance layer, and the lower electrode layer.

14. The manufacturing method of claim 13, wherein the variable resistance layer includes a phase change material.

15. The manufacturing method of claim 13, wherein the variable resistance layer includes a chalcogenide material maintaining its phase after a program operation.

16. The manufacturing method of claim 13, wherein the forming of the first access lines comprises:
forming a second conductive layer on the first memory stack lines;
forming a second mask pattern on the second conductive layer; and
etching the second conductive layer using the second mask pattern as an etching barrier.

17. The manufacturing method of claim 16, wherein the first mask pattern and the second mask pattern have a same shape.

18. The manufacturing method of claim 2, wherein the forming of the first memory stack lines further comprises:
forming a switching layer having a threshold switching characteristics for blocking or limiting current based a voltage applied to the switching layer.

19. The manufacturing method of claim 18, wherein the first memory cells operate as at least one of a memory element or a switch element.

20. The manufacturing method of claim 13, wherein the forming of the first memory stack lines further comprises:
forming a switching layer having a threshold switching characteristics for blocking or limiting current based a voltage applied to the switching layer.
